(19) United States
(12) Patent Application Publication
(10) Pub. No.: US 2021/0013416 A1
(43) Pub. Date: Jan. 14, 2021

(54) DISPLAY PANEL AND DISPLAY DEVICE

(71) Applicant: SHENZHEN CHINA STAR OPTOELECTRONICS TECHNOLOGY CO., LTD., Guangdong (CN)

(72) Inventor: Bao ZHA, Guangdong (CN)

(21) Appl. No.: 16/609,340

(22) PCT Filed: Aug. 16, 2019
(86) PCT No.: PCT/CN2019/100909

§ 371 Date: Oct. 29, 2019

(30) Foreign Application Priority Data
Jul. 9, 2019 (CN) 201910614388.7

(51) Int. Cl. H01L 51/00

(52) U.S. Cl. CPC H01L 51/0036; H01L 51/5056; H01L 51/0089

(57) ABSTRACT

The present disclosure provides a display panel and a display device. The display panel includes an anode layer, a hole transport layer, an emission layer, an electron transport layer, and a cathode layer, and the emission layer is made of lanthanide-based metal polymer. The technical effect of the present disclosure is to improve the luminous stability of the display device, and improve the service life of the display panel.

### FIELD OF INVENTION

The present disclosure relates to the field of display, and particularly relates to a display panel and a display device.

### BACKGROUND OF INVENTION

As a kind of organic electroluminescence, applications of organic light emitting diodes (OLEDs) in illumination and display are known as next-generation display technology, which has been widely recognized by the industry and become a research hotspot. OLED-based displays have the three primary colors (red, green, and blue) in the visible light region. Currently, most OLED backlights are mainly illuminated by electroluminescent organic materials, and stability and service life of organic light-emitting materials are important factors that limit display applications of OLEDs. Although after years of research by scientists, the service life of related luminescent materials has been greatly improved, it is still difficult to compare OLEDs with liquid crystal displays (LCDs). Therefore, solving the problem of the service life of luminescent materials is the problem that requires to be solved urgently.

### SUMMARY OF INVENTION

The purpose of the present disclosure is to solve the technical problem that the luminescent material of the emission layer in the current display panel has a low service life.

For realizing the purpose mentioned above, the present disclosure provides a display panel, which includes: an anode layer; a hole transport layer disposed on a surface of a side of the anode layer; an emission layer disposed on a surface of a side of the hole transport layer away from the anode layer; an electron transport layer disposed on a surface of a side of the emission layer away from the hole transport layer; and a cathode layer disposed on a surface of a side of the electron transport layer away from the emission layer; and the emission layer is lanthanide-based metal polymer.

Further, the lanthanide-based metal polymer is polymerized from intrinsically conductive polymer and a lanthanide-based metal material.

Further, the lanthanide-based metal material includes any of europium, terbium, lanthanum, and dysprosium.

Further, a structural formula of the intrinsically conductive polymer is:

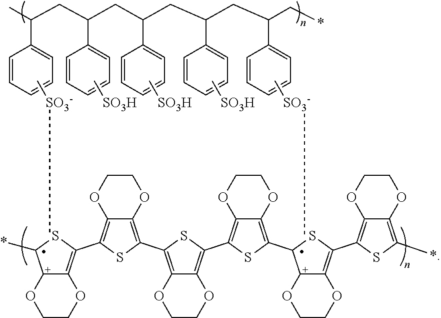

Further, the emission layer includes a red emission layer, a green emission layer, and a blue emission layer which are arranged side by side; or the emission layer includes a red emission layer, a yellow emission layer, a green emission layer, and a blue emission layer which are arranged side by side.

Further, the red emission layer is made of europium polymer, and a structural formula of the europium polymer is:

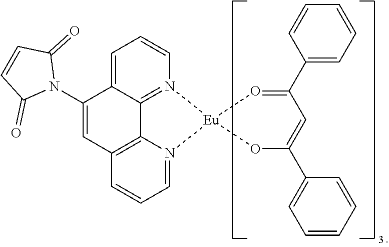

Further, material of the green emission layer is terbium polymer; a structural formula of the terbium polymer is:

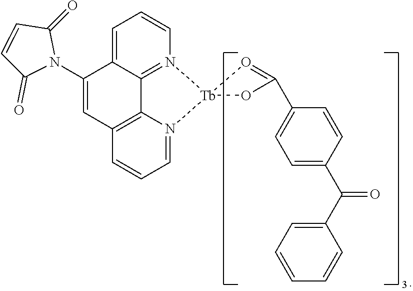

Further, the blue emission layer is made of lanthanum polymer, and a structural formula of the lanthanum polymer is:

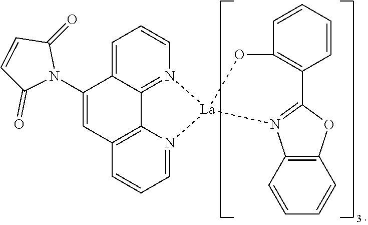

Further, the yellow emission layer is made of dysprosium polymer, and a structural formula of the dysprosium polymer is:

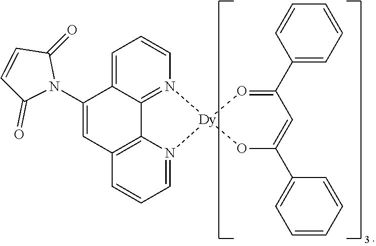

For realizing the purpose mentioned above, the present disclosure further provides a display device, which includes the display panel mentioned above.

The technical effect of the present disclosure is that since the lanthanide-based metal material can generally be formed into a stable oxidation state, and the lanthanide-based metal material has a high fluorescence characteristic and high structural stability, so the lanthanide-based metal material is used to prepare the emission layer, which can improve luminous stability of the display device, and meanwhile the service life of the lanthanide-based metal material is higher than that of organic luminescent material, which can further extend the service life of the display device.

### DESCRIPTION OF DRAWINGS

FIG. 1 is a structural schematic diagram of a display panel of a first embodiment of the present disclosure.

FIG. 2 is a structural schematic diagram of a display panel of a second embodiment of the present disclosure.

### DETAILED DESCRIPTION OF PREFERRED EMBODIMENTS

The preferred embodiments of the present disclosure are described in detail below with reference to the accompanying figures to completely introduce technical content of the present disclosure to those skilled in the art, and to give an example that the present disclosure can be implemented. This makes the technical content of the present disclosure will be clearer and those skilled in the art will more readily understand how to implement the present disclosure. However, the present disclosure can be implemented in many different forms of embodiments. The scope of the present disclosure is not limited to the embodiments mentioned herein, and the description of the embodiments below is not intended to limit the scope of the present disclosure.

The directional terms of which the present disclosure mentions, for example, “top,” “bottom,” “upper,” “lower,” “front,” “rear,” “left,” “right,” “inside,” “outside,” “side,” etc., are just refer to directions of the accompanying figures. The directional terms used herein are used to explain and describe the present disclosure, and are not intended to limit the scope of the present disclosure.

In the accompanying figures, elements with same structures are used same labels to indicate, and components that have similar structure or function are denoted by similar labels. Moreover, for ease of understanding and description, the dimensions and thickness of each component shown in the accompanying figures are arbitrarily shown, and the present disclosure does not limit the dimensions and thickness of each component.

When a component is described as “on” another component, the component can be placed directly on the other component; there can also be an intermediate component, the component is placed on the intermediate component, and the intermediate component is placed on another component. When a component is described as “mounted” or “connected to” another component, it can be understood as “directly mounted” or “directly connected to”, or a component is “mounted” or “connected to” through an intermediate component to another component.

### The First Embodiment

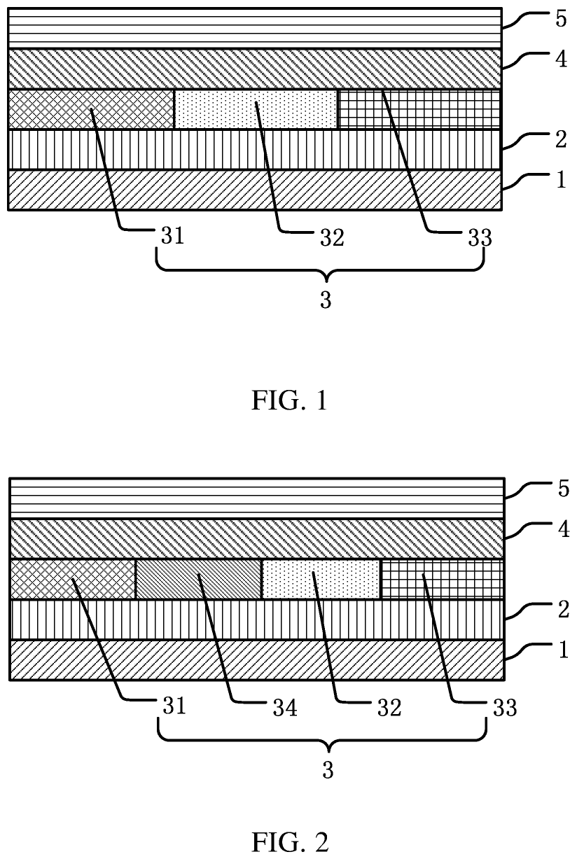

This embodiment provides a display device. The display device may be a smart phone, a tablet computer, a notebook, an LCD TV, etc. The display device includes a display panel as illustrated in FIG. 1, and the display panel includes an anode layer 1, a hole transport layer 2, an emission layer 3, an electron transport layer 4, and a cathode layer 5.

The anode layer 1 is electrically connected to a thin film transistor (TFT) of the display panel, and obtains an electric signal from the TFT to provide the electric signal to the emission layer 3. The anode layer 1 is made of material having high work function, which generally is indium tin oxide (ITO), indium zinc oxide (IZO), gold (Au), platinum (Pt), silicon (Si), and so on. Electron holes are injected from the anode layer 1 to the hole transport layer 2. The electron holes are transferred to the emission layer 3 by passing through the hole transport layer 2 and meet electrons in the emission layer 3 to form excitons and make luminescent molecules excite. The luminescent molecules emit visible light through radiation relaxation.

When there are charge carriers (electron holes) injected into the hole transport layer (HTL) 2, directed orderly controllable migration of the electron holes can be realized in an electric field, thereby achieving a function of electric charge transfer. The hole transport layer 2 is made of organic semiconductor material, and the organic semiconductor material is an aromatic amine fluorescent polymer such as TPD, and TDATA, etc.

The emission layer 3 (EML) is made of lanthanide-based metal polymer, which is polymerized from a lanthanide-based metal material and an intrinsically conductive polymer (PEDOT:PSS). The lanthanide-based metal material and the organic intrinsically conductive high molecular polymer can be used to form the lanthanide-based metal polymer by a Diels-Alder reaction.

When a lanthanide element is in a gaseous state, the ionization energy required to lose two 6s electrons and one 5d electron, or to lose two 6s electrons and one 4f electron is relatively low, so that a stable +3 oxidation state is generally attained. In addition to having the characteristic of +3 oxidation states, there are some uncommon oxidation states in lanthanide elements. For example, cerium, praseodymium, neodymium, terbium, and dysprosium have +4 oxidation states, the reason is that their 4f shells is relatively stable when remain or close a condition of full, half full, or completely filled. Similarly, cerium, neodymium, samarium, europium, and thulium further have +2 oxidation states. Therefore, the structure of the oxidation state of the lanthanide-based metal is stable.

The emission layer 3 is for emitting light. When the emission layer 3 is injected with the electron holes of the hole transport layer 2 and the electrons of the electron transport layer 4, the high molecular intrinsically conductive polymer (PEDOT:PSS) acts as a conductor, and the emission layer 3 can be excited to emit light. Based on the difference of the selected material system, different colors of light are emitted. In this embodiment, the emission layer 3 emits red, green, and blue light. The emission layer 3 includes a red emission layer 31, a green emission layer 32, and a blue emission layer 33 which are arranged side by side.

When the red emission layer 31 is injected with the electron holes of the hole transport layer 2 and the electrons of the electron transport layer 4, the high molecular intrinsically conductive polymer (PEDOT:PSS) acts as a conductor, and the red emission layer 31 can be excited to emit light. The red emission layer 31 emits red light. The red emission layer 31 is made of europium polymer. The europium polymer is a polymer polymerized from europium (Eu) and high molecular intrinsically conductive polymer (PEDOT:PSS) by the above-mentioned Diels-Alder reaction. A structural formula of the europium polymer is:

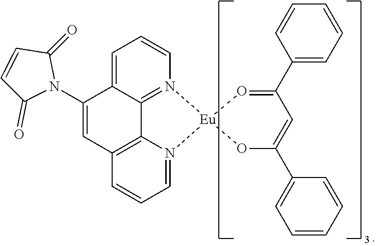

The europium ions of the europium polymer are bonded to two carbon atoms and two nitrogen atoms to form four covalent bonds, and a stable molecular structure is formed among the four covalent bonds, so that the structure of the europium polymer is highly stable.

When the green emission layer 32 is injected with the electron holes of the hole transport layer 2 and the electrons of the electron transport layer 4, the high molecular intrinsically conductive polymer (PEDOT:PSS) acts as a conductor, and the green emission layer 32 can be excited to emit light. The green emission layer 32 emits green light. The green emission layer 32 is made of terbium polymer. The terbium polymer is a polymer polymerized from terbium (Tb) and high molecular intrinsically conductive polymer (PEDOT:PSS) by the above-mentioned Diels-Alder reaction. A structural formula of the terbium polymer is:

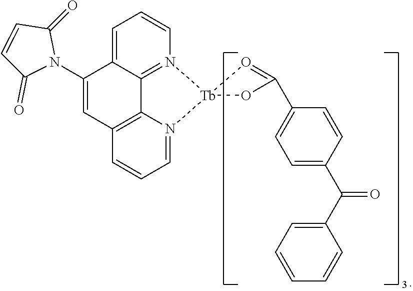

The terbium ions of the terbium polymer are bonded to two carbon atoms and two nitrogen atoms to form four covalent bonds, and a stable molecular structure is formed among the four covalent bonds, so that the structure of the terbium polymer is with high stability.

When the blue emission layer 33 is injected with the electron holes of the hole transport layer 2 and the electrons of the electron transport layer 4, the high molecular intrinsically conductive polymer (PEDOT:PSS) acts as a conductor, and the blue emission layer 33 can be excited to emit light. The blue emission layer 33 emits blue light. The blue emission layer 33 is made of lanthanum polymer. The lanthanum polymer is a polymer polymerized from lanthanum (La) and the high molecular intrinsically conductive polymer (PEDOT:PSS) by the above-mentioned Diels-Alder reaction. A structural formula of the lanthanum polymer is:

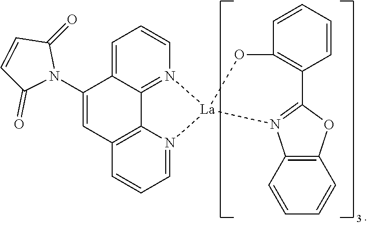

The lanthanum ions of the lanthanum polymer are bonded to two carbon atoms and two nitrogen atoms to form four covalent bonds, and a stable molecular structure is formed among the four covalent bonds, so that the structure of the lanthanum polymer is with high stability.

When there are charge carriers (electrons) injected into the electron transport layer (ETL) 4, the directed orderly controllable migration of electrons can be realized in an electric field, thereby achieving a function of transporting electrons. The electron transport layer 4 is made of organic semiconductor material, and the organic semiconductor material has high film stability, heat stability, and a good electron transport property, which is usually a fluorescent dye polymer such as Alq, Znq, Gaq, Bebq, Balq, DPVBi, ZnSPB, PBD, OXD, and BBOT.

The cathode layer 5 is made of material having low work function, which generally includes elemental metal or alloy material. The elemental metal includes silver (Ag), aluminum (Al), lithium (Li), magnesium (Mg), and calcium (Ca), indium (In), etc., and the alloy material includes magnesium-aluminum alloy (Mg:Ag (10:1)), lithium-aluminum alloy (Li:Al (0.6% Li)). Electrons are injected from the cathode layer 5 to the electron transport layer 4. The electrons are transferred to the emission layer 3 by passing through the electron transport layer 4 and meet electron holes in the emission layer 3 to form excitons and make luminescent molecules excite. The luminescent molecules emit visible light through radiation relaxation.

The technical effect of the present disclosure is that since the lanthanide-based metal material can generally be attained into a stable oxidation state, and the lanthanide-based metal material has a high fluorescence characteristic and high structural stability, so the lanthanide-based metal material is used to prepare the emission layer, which can improve luminous stability of the display device, and meanwhile the service life of the lanthanide-based metal material is higher than that of organic luminescent materials, which can further extends the service life of the display device.

### The Second Embodiment

This embodiment provides a display device. The display device may be a smart phone, a tablet computer, a notebook, an LCD TV, etc. The display device includes a display panel as illustrated in FIG. 2, and the display panel includes an anode layer 1, a hole transport layer 2, an emission layer 3, an electron transport layer 4, and a cathode layer 5.

The anode layer 1 is electrically connected to a thin film transistor (TFT) of the display panel, and obtains an electric signal from the TFT to provide the electric signal to the emission layer 3. The anode layer 1 is made of material having high work function, which generally is indium tin oxide (ITO), indium zinc oxide (IZO), gold (Au), platinum (Pt), silicon (Si), and so on. Electron holes are injected from the anode layer 1 to the hole transport layer 2. The electron holes are transferred to the emission layer 3 by passing through the hole transport layer 2 and meet electrons in the emission layer 3 to form excitons and make luminescent molecules excite. The luminescent molecules emit visible light through radiation relaxation.

When there are charge carriers (electron holes) injected into the hole transport layer (HTL) 2, directed orderly controllable migration of the electron holes can be realized in an electric field, thereby achieving a function of electric charge transfer. The hole transport layer 2 is made of organic semiconductor material, and the organic semiconductor material is an aromatic amine fluorescent polymer, such as TPD, and TDATA, etc.

The emission layer 3 (EML) is made of lanthanide-based metal polymer, which is polymerized from a lanthanide-based metal material and intrinsically conductive polymer (PEDOT:PSS). The lanthanide-based metal material and the organic intrinsically conductive high molecular polymer can be used to form the lanthanide-based metal polymer by a Diels-Alder reaction.

When a lanthanide element is in a gaseous state, the ionization energy required to lose two 6s electrons and one 5d electron, or to lose two 6s electrons and one 4f electron is relatively low, so that a stable +3 oxidation state is generally attained. In addition to having the characteristic of +3 oxidation states, there are some uncommon oxidation states in lanthanide elements. For example, cerium, praseodymium, neodymium, terbium, and dysprosium have +4 oxidation states, the reason is that their 4f shells is relatively stable when remain or close a condition of full, half full, or completely filled. Similarly, cerium, neodymium, samarium, europium, and thulium further have +2 oxidation states. Therefore, the structure of the oxidation state of the lanthanide-based metal is stable.

The emission layer 3 is for emitting light. When the emission layer 3 is injected with the electron holes of the hole transport layer 2 and the electrons of the electron transport layer 4, the high molecular intrinsically conductive polymer (PEDOT:PSS) acts as a conductor, and the emission layer 3 can be excited to emit light. Based on the difference of the selected material system, different colors of light are emitted. In this embodiment, the emission layer 3 emits red, yellow, green and blue light. Compared with the first embodiment, a yellow emission layer 34 is added in this embodiment for emitting yellow light. The emission layer 3 includes a red emission layer 31, a yellow emission layer 34, a green emission layer 32, and a blue emission layer 33 which are arranged side by side.

When the red emission layer 31 is injected with the electron holes of the hole transport layer 2 and the electrons of the electron transport layer 4, the high molecular intrinsically conductive polymer (PEDOT:PSS) acts as a conductor, and the red emission layer 31 can be excited to emit light. The red emission layer 31 emits red light. The red emission layer 31 is made of europium polymer. The europium polymer is a polymer polymerized from europium (Eu) and high molecular intrinsically conductive polymer (PEDOT:PSS) by the above-mentioned Diels-Alder reaction. A structural formula of the europium polymer is:

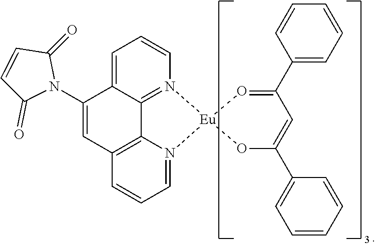

The europium ions of the europium polymer are bonded to two carbon atoms and two nitrogen atoms to form four covalent bonds, and a stable molecular structure is formed among the four covalent bonds, so that the structure of the europium polymer is with high stability.

When the yellow emission layer 34 is injected with the electron holes of the hole transport layer 2 and the electrons of the electron transport layer 4, the high molecular intrinsically conductive polymer (PEDOT:PSS) acts as a conductor, and the yellow emission layer 34 can be excited to emit light. The yellow emission layer 34 emits yellow light. The yellow emission layer 34 is made of dysprosium polymer. The dysprosium polymer is a polymer polymerized from dysprosium (Dy) and high molecular intrinsically conductive polymer (PEDOT:PSS) by the above-mentioned Diels-Alder reaction. A structural formula of the dysprosium polymer is:

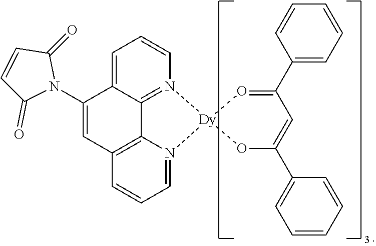

The dysprosium ions of the dysprosium polymer are bonded to two carbon atoms and two nitrogen atoms to form four covalent bonds, and a stable molecular structure is formed among the four covalent bonds, so that the structure of the dysprosium polymer is with high stability.

When the green emission layer 32 is injected with the electron holes of the hole transport layer 2 and the electrons of the electron transport layer 4, the high molecular intrinsically conductive polymer (PEDOT:PSS) acts as a conductor, and the green emission layer 32 can be excited to emit light. The green emission layer 32 emits green light. The green emission layer 32 is made of terbium polymer. The terbium polymer is a polymer polymerized from terbium (Tb) and high molecular intrinsically conductive polymer (PEDOT:PSS) by the above-mentioned Diels-Alder reaction. A structural formula of the terbium polymer is:

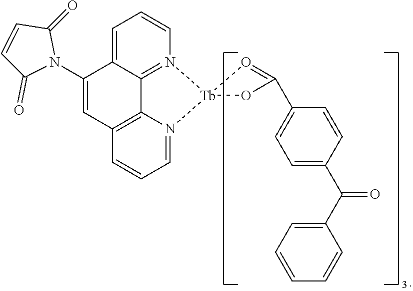

The terbium ions of the terbium polymer are bonded to two carbon atoms and two nitrogen atoms to form four covalent bonds, and a stable molecular structure is formed among the four covalent bonds, so that the structure of the terbium polymer is with high stability.

When the blue emission layer 33 is injected with the electron holes of the hole transport layer 2 and the electrons of the electron transport layer 4, the high molecular intrinsically conductive polymer (PEDOT:PSS) acts as a conductor, and the blue emission layer 33 can be excited to emit light. The blue emission layer 33 emits blue light. The blue emission layer 33 is made of lanthanum polymer. The lanthanum polymer is a polymer polymerized from lanthanum (La) and high molecular intrinsically conductive polymer (PEDOT:PSS) by the above-mentioned Diels-Alder reaction. A structural formula of the lanthanum polymer is:

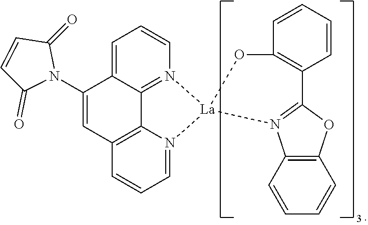

The lanthanum ions of the lanthanum polymer are bonded to two carbon atoms and two nitrogen atoms to form four covalent bonds, and a stable molecular structure is formed among the four covalent bonds, so that the structure of the lanthanum polymer is with high stability.

When there are charge carriers (electrons) injected into the electron transport layer (ETL) 4, the directed orderly controllable migration of electrons can be realized in an electric field, thereby achieving a function of transporting electrons. The electron transport layer 4 is made of organic semiconductor material, and the organic semiconductor material has high film stability, heat stability, and a good electron transport property, which usually is a fluorescent dye polymer such as, Alq, Znq, Gaq, Bebq, Balq, DPVBi, ZnSPB, PBD, OXD, and BBOT.

The cathode layer 5 is made of material having low work function, which generally includes elemental metal or alloy material. The elemental metal includes silver (Ag), aluminum (Al), lithium (Li), magnesium (Mg), and calcium (Ca), indium (In), etc., and the alloy material includes magnesium-aluminum alloy (Mg:Ag (10:1)), lithium-aluminum alloy (Li:Al (0.6% Li)). Electrons are injected from the cathode layer 5 to the electron transport layer 4. The electrons are transferred to the emission layer 3 by passing through the electron transport layer 4 and meet electron holes in the emission layer 3 to form excitons and make luminescent molecules excite. The luminescent molecules emit visible light through radiation relaxation.

The technical effect of the present disclosure is that since the lanthanide-based metal material can generally be formed into a stable oxidation state, and the lanthanide-based metal material has high structural stability, so the lanthanide-based metal material is used to prepare the emission layer, which can improve the luminous stability of the display device, while the service life of the lanthanide-based metal material is higher than that of the organic luminescent material, which can further extend the service life of the display device.

Which mentioned above is preferred embodiments of the present disclosure, it should be noted that to those skilled in the art without departing from the technical theory of the present disclosure, can further make many changes and modifications, and the changes and the modifications should be considered as the scope of protection of the present disclosure.

What is claimed is:

1. A display panel, comprising:
an anode layer;
a hole transport layer disposed on a surface of a side of the anode layer;
an emission layer disposed on a surface of a side of the hole transport layer away from the anode layer;
an electron transport layer disposed on a surface of a side of the emission layer away from the hole transport layer; and
a cathode layer disposed on a surface of a side of the electron transport layer away from the emission layer;
wherein the emission layer is made of lanthanide-based metal polymer.

2. The display panel as claimed in claim 1, wherein the lanthanide-based metal polymer is polymerized from intrinsically conductive polymer and a lanthanide-based metal material.

3. The display panel as claimed in claim 2, wherein
the lanthanide-based metal material comprises any of europium, terbium, lanthanum, and dysprosium.

4. The display panel as claimed in claim 2, wherein a structural formula of the intrinsically conductive polymer is:

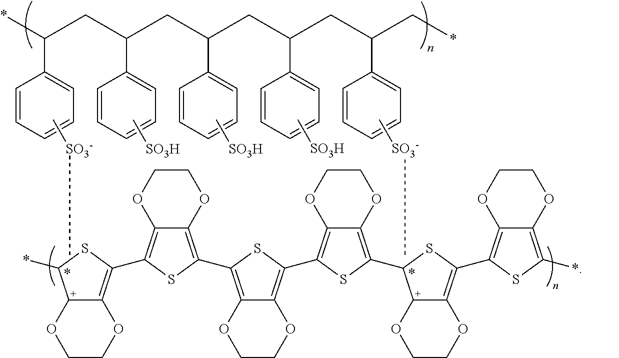

5. The display panel as claimed in claim 2, wherein the emission layer comprises a red emission layer, a green emission layer, and a blue emission layer which are arranged side by side; or
the emission layer comprises a red emission layer, a yellow emission layer, a green emission layer, and a blue emission layer which are arranged side by side.

6. The display panel as claimed in claim 5, wherein
the red emission layer is made of europium polymer, and a structural formula of the europium polymer is:

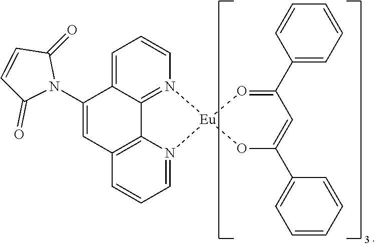

7. The display panel as claimed in claim 5, wherein the green emission layer is made of terbium polymer, and a structural formula of the terbium polymer is:

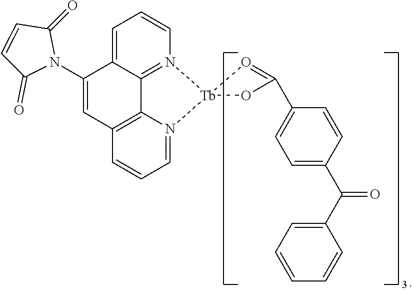

8. The display panel as claimed in claim 5, wherein
the blue emission layer is made of lanthanum polymer, and a structural formula of the lanthanum polymer is:

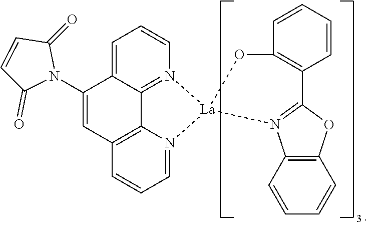

9. The display panel as claimed in claim 5, wherein the yellow emission layer is made of dysprosium polymer, and a structural formula of the dysprosium polymer is:

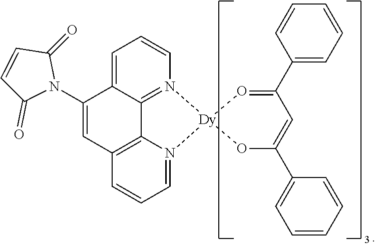

10. A display device, comprising the display panel as claimed in claim 1.
